(19) United States
(12) Patent Application Publication
(10) Pub. No.: US 2012/0121895 A1
(43) Pub. Date: May 17, 2012

(54) ANTI-CORROSION TREATMENT PROCESS FOR ALUMINUM OR ALUMINUM ALLOY AND ALUMINUM OR ALUMINUM ALLOY ARTICLE THEREOF

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); NAN MA, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/176,302

(22) Filed: Jul. 5, 2011

(30) Foreign Application Priority Data
Nov. 12, 2010 (CN) 201010541524.3

(51) Int. Cl. B32B 3/00; C23C 14/35; B32B 15/04; C23C 14/06

(52) U.S. Cl. 428/336; 204/192.1; 204/192.15; 428/457

(57) ABSTRACT

An aluminum or aluminum alloy article is described. The aluminum or aluminum alloy article includes an aluminum or aluminum alloy substrate, a color layer formed on the substrate, and an insulation layer formed on the color layer. The color layer is formed by vacuum sputtering. The insulation layer is an external layer of the aluminum or aluminum article.

### CROSS-REFERENCE TO RELATED APPLICATIONS

This application is one of the three related co-pending U.S. patent applications listed below. All listed applications have the same assignee. The disclosure of each of the listed applications is incorporated by reference into the other listed applications.

| Attorney | | |
|---|---|---|
| Docket | | |
| No. | Title | Inventors |
| US 35689 | ANTI-CORROSION TREATMENT PROCESS | HSIN-PEI |
| | FOR ALUMINUM OR ALUMINUM ALLOY | CHANG |
| | AND ALUMINUM OR ALUMINUM ALLOY | et al. |
| | ARTICLE THEREOF | |
| US 35696 | ANTI-CORROSION TREATMENT PROCESS | HSIN-PEI |
| | FOR ALUMINUM OR ALUMINUM ALLOY | CHANG |
| | AND ALUMINUM OR ALUMINUM ALLOY | et al. |
| | ARTICLE THEREOF | |
| US 38618 | ANTI-CORROSION TREATMENT PROCESS | HSIN-PEI |
| | FOR ALUMINUM OR ALUMINUM ALLOY | CHANG |
| | AND ALUMINUM OR ALUMINUM ALLOY | et al. |
| | ARTICLE THEREOF | |

### BACKGROUND

1. Technical Field

The present disclosure relates to an anti-corrosion treatment process for aluminum or aluminum alloy and aluminum or aluminum alloy article thereof.

2. Description of Related Art

Aluminum or aluminum alloy is widely used for its excellent properties. However, the aluminum or aluminum alloy is prone to corrosion because the aluminum or aluminum alloy has a very low standard electrode potential. To protect the aluminum or aluminum alloy from corrosion, an insulation layer may be formed between the aluminum or aluminum alloy and a vacuum deposited protective layer to prevent a galvanic corrosion forming in the layers and the aluminum or aluminum alloy. However, since the layers almost always have pinholes and cracks formed therein, the corrosives can permeate the layers and can cause a galvanic cell in the protective layer and the aluminum or aluminum alloy. The protective layer may become a cathode of the galvanic cell and the aluminum or aluminum alloy may become an anode of the galvanic cell. Because the surface area of the cathode is much more than the surface area of the anode (small portion surface of the aluminum or aluminum alloy), a big corrosion current of the galvanic cell will be created in the protective layer and the aluminum or aluminum alloy. As such, the protective layer and the aluminum or aluminum alloy are quickly corroded.

Therefore, there is room for improvement within the art.

### BRIEF DESCRIPTION OF THE FIGURES

Many aspects of the disclosure can be better understood with reference to the following figures. The components in the figures are not necessarily drawn to scale, the emphasis instead being placed upon clearly illustrating the principles of the disclosure. Moreover, in the drawings like reference numerals designate corresponding parts throughout the several views.

FIG. 1 is a cross-sectional view of an exemplary embodiment of an aluminum or aluminum alloy article.

FIG. 2 is an overlook view of an exemplary embodiment of a vacuum sputtering device.

### DETAILED DESCRIPTION

According to an exemplary embodiment, an anti-corrosion treatment process for aluminum or aluminum alloy may include the following steps:

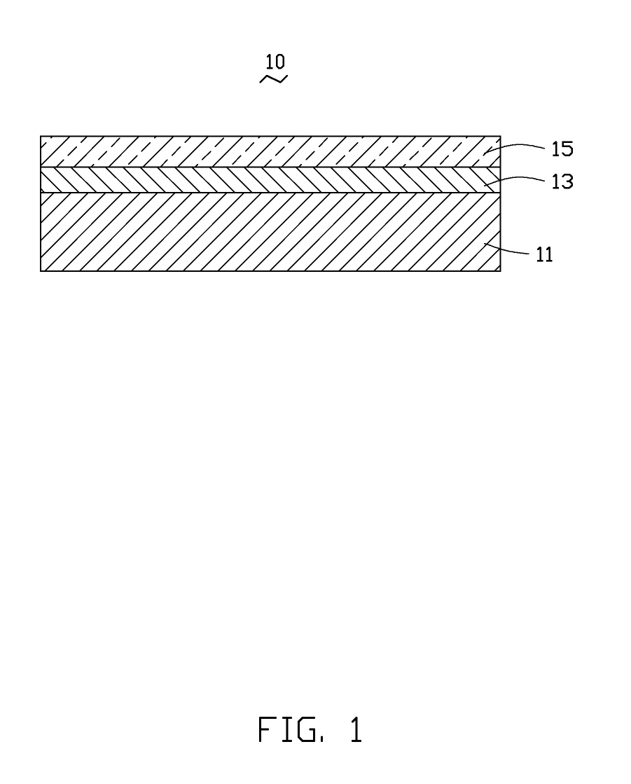

Referring to FIG. 1, an aluminum or aluminum alloy substrate 11 is provided. The substrate 11 is then pre-treated. The pre-treating process may include the following steps:

The substrate 11 is cleaned in an ultrasonic cleaning device (not shown) filled with ethanol or acetone.

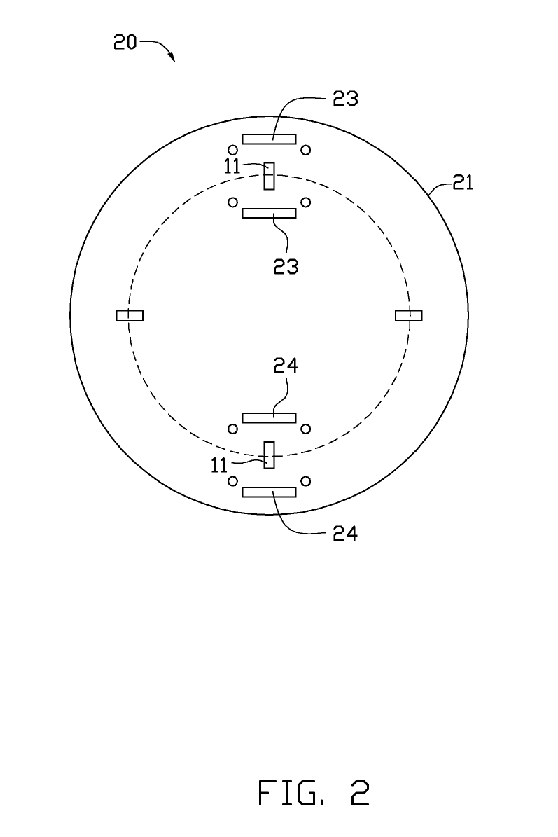

The substrate 11 is plasma cleaned. Referring to FIG. 2, the substrate 11 may be positioned in a coating chamber 21 of a vacuum sputtering device 20. Silicon targets 23 and titanium targets 24 are fixed in the coating chamber 21. The coating chamber 21 is then evacuated to about 8.0×10⁻³ Pa. Argon gas having a purity of about 99.999% may be used as a working gas and is injected into the coating chamber 21 at a flow rate of about 100 standard-state cubic centimeters per minute (sccm) to 200 sccm. The substrate 11 may have a negative bias voltage of about −300 V to about −500 V, then high-frequency voltage is produced in the coating chamber 21 and the argon gas is ionized to plasma. The plasma then strikes the surface of the substrate 11 to clean the surface of the substrate 11. Plasma cleaning of the substrate 11 may take about 5 minutes (min) to 10 min. The plasma cleaning process enhances the bond between the substrate 11 and the subsequent layers. The silicon and titanium targets are unaffected by the pre-cleaning process.

A color layer 13 may be magnetron sputtered on the pretreated substrate 11 by using a power at an intermediate frequency for the titanium targets 24. Magnetron sputtering of the color layer 13 is implemented in the coating chamber 21. The internal temperature of the coating chamber 21 may be of about 20° C.-120° C. Nitrogen (N₂) may be used as a reaction gas and is injected into the coating chamber 21 at a flow rate of about 20 sccm-120 sccm, and argon gas may be used as a working gas and is injected into the coating chamber 21 at a flow rate of about 100 sccm-200 sccm. The power at an intermediate frequency and at a level of 8 kilowatt (KW)-10 KW is applied to the titanium targets 24, then titanium atoms are sputtered off from the titanium targets 24. The titanium atoms and nitrogen atoms are then to be ionized at an electrical field in the coating chamber 21. The ionized titanium chemically reacts with the ionized nitrogen to form the color layer 13 of titanium nitride (TiN) on the substrate 11. During the depositing process, the substrate 11 may have a negative bias voltage of about −150 V to about −500 V. Depositing of the color layer 13 may take about 15 min-30 min.

The color layer 13 is a layer of titanium nitride (TiN). The color layer 13 has a thickness of about 200 nm-400 nm.

After the color layer 13 being deposited, the coating chamber 21 is then evacuated for about 10 min to exhaust the nitrogen that may have been in the coating chamber 21.

An insulation layer 15 may be sputtered on the color layer 13 by using a power at a radio frequency for the silicon targets 23. Sputtering of the insulation layer 15 is implemented in the coating chamber 21. The internal temperature of the coating chamber 21 may be of about 20° C.-120° C. Oxygen (O₂) may be used as a reaction gas and is injected into the coating chamber 21 at a flow rate of about 40 sccm-60 sccm, and argon gas may be used as a working gas and is injected into the coating chamber 21 at a flow rate of about 100 sccm-200 sccm. The power at a radio frequency and at a level of 8 kilowatt (KW)-10 KW is applied to the silicon targets 23, and the silicon atoms are sputtered off from the silicon targets 23. The silicon atoms and nitrogen atoms are then to be ionized in an electrical field in the coating chamber 21. The ionized silicon chemically reacts with the ionized nitrogen to deposit the insulation layer 15 of silicon dioxide (SiO₂) on the color layer 13. During the depositing process, the substrate 11 may have a negative bias voltage of about −150 V to about −500 V. Depositing of the insulation layer 15 may take about 40 min-70 min.

The insulation layer 15 is a transparent layer of silicon dioxide (SiO₂). The insulation layer 15 has a thickness of about 200 nm-500 nm.

It is to be understood that, the silicon dioxide can also be formed by arc ion plating or evaporation deposition.

It is to be understood that the color layer 13 can also be a layer of titanium-carbon-nitrogen (TiCN), chromium nitride (CrN), chromium-carbon-nitrogen (CrCN), or any other decorative layers formed by vacuum sputtering or arc ion plating.

It is to be understood that the insulation layer 15 can also be a transparent aluminum oxide (Al₂O₃) layer formed by vacuum sputtering, arc ion plating, or evaporation deposition, a layer of polytetrafluoroethylene formed by chemical vacuum deposition or spraying, or a layer of insulative paint or insulative ink formed by spraying or printing.

FIG. 1 shows an aluminum or aluminum alloy article 10 formed by the exemplary method. The aluminum or aluminum alloy article 10 includes the aluminum or aluminum alloy substrate 11, the color layer 13 formed on a surface of the substrate 11, and the insulation layer 15 formed on the color layer 13.

In the exemplary embodiment, the insulation layer 15 is the outermost layer. The insulation layer 15 blocks most corrosives, so only a small amount of the corrosives may enter through the pinholes or cracks of the color layer 13 and transit to a small portion surface of the substrate 11. Thus even if a galvanic cell is created in the color layer 13 and the substrate 11, the color layer 13, namely the cathode, has a very small surface area and may be proportional to the anode surface area (the small surface area of the substrate 11), then the corrosion current of the galvanic cell is very small and the corroding of the color layer 13 and the substrate 11 is greatly reduced. As such, the corrosion resistance property of the aluminum or aluminum alloy article 10 is achieved.

Additionally, the insulation layer 15 is transparent, which will not affect the decoration of the color layer 13 for the aluminum or aluminum alloy article 10.

It is to be understood that, the insulation layer 15 can also be opaque if a decorative appearance is not requested.

A salt spray test has been performed on the aluminum or aluminum alloy articles 10. The salt spray test uses a sodium chloride (NaCl) solution having a mass concentration of 5% at a temperature of 35° C. The test indicates that the corrosion resistance property of the aluminum or aluminum alloy article 10 lasts more than 72 hours, thus, the aluminum or aluminum alloy article 10 has an excellent corrosion resistance property.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. An aluminum or aluminum alloy article, comprising:
an aluminum or aluminum alloy substrate;
a color layer formed on the substrate, the color layer being formed by vacuum sputtering; and
an insulation layer formed on the color layer, the insulation layer being an external layer of the aluminum or aluminum article.

2. The aluminum or aluminum alloy article as claimed in claim 1, wherein the color layer is a layer of titanium nitride and has a thickness of about 200 nm-400 nm.

3. The aluminum or aluminum alloy article as claimed in claim 1, wherein the color layer is a layer of titanium-carbon-nitrogen, chromium nitride, or chromium-carbon-nitrogen formed by vacuum sputtering or arc ion plating.

4. The aluminum or aluminum alloy article as claimed in claim 1, wherein the insulation layer is a layer of silicon dioxide formed by vacuum sputtering, arc ion plating, or evaporation deposition.

5. The aluminum or aluminum alloy article as claimed in claim 4, wherein the silicon dioxide layer has a thickness of about 200 nm-500 nm.

6. The aluminum or aluminum alloy article as claimed in claim 1, wherein the insulation layer is a layer of aluminum oxide formed by vacuum sputtering, arc ion plating, or evaporation deposition.

7. The aluminum or aluminum alloy article as claimed in claim 1, wherein the insulation layer is a layer of polytetrafluoroethylene formed by chemical vacuum deposition or spraying.

8. The aluminum or aluminum alloy article as claimed in claim 1, wherein the insulation layer is a layer of insulative paint or insulative ink formed by spraying or printing.

9. An anti-corrosion treatment process for aluminum or aluminum alloy, comprising:
providing an aluminum or aluminum alloy substrate; and
forming a color layer on the substrate by vacuum sputtering; and
forming an insulation layer on the color layer, the insulation layer being an external layer.

10. The process as claimed in claim 9, wherein the color layer is a layer of titanium nitride, forming the color layer is by using a magnetron sputtering process, uses titanium target, the titanium target is applied with a power at an intermediate frequency and at a level of about 8 KW-10 KW; uses nitrogen as a reaction gas, the nitrogen has a flow rate of about 20 sccm-120 sccm; uses argon as a working gas, the argon has a flow rate of about 100 sccm-200 sccm; magnetron sputtering of the color layer is conducted at a temperature of about 20° C.-120° C. and takes about 15 min-30 min.

11. The process as claimed in claim 10, wherein the substrate has a negative bias voltage of about −150V to about −500V during sputtering the color layer.

12. The process as claimed in claim 9, wherein the color layer is a layer of titanium-carbon-nitrogen, chromium nitride, or chromium-carbon-nitrogen formed by vacuum sputtering or arc ion plating.

13. The process as claimed in claim 9, wherein the insulation layer is a layer of silicon dioxide, forming the insulation layer is by using a vacuum sputtering process, uses silicon target, the silicon target is applied with a power at a radio frequency and at a level of about 8 KW-10 KW; uses oxygen as a reaction gas, the oxygen has a flow rate of about 40 sccm-60 sccm; uses argon as a working gas, the argon has a flow rate of about 100 sccm-200 sccm; vacuum sputtering of the insulation layer is conducted at a temperature of about 20° C.-120° C. and takes about 40 min-70 min.

14. The process as claimed in claim 13, wherein the substrate has a negative bias voltage of about −150V to about −500V during sputtering the insulation layer.

15. The process as claimed in claim 9, wherein the insulation layer is a layer of aluminum oxide formed by vacuum sputtering, arc ion plating, or evaporation deposition.

16. The process as claimed in claim 9, wherein the insulation layer is a layer of polytetrafluoroethylene formed by chemical vacuum deposition or spraying.

17. The process as claimed in claim 9, wherein the insulation layer is a layer of insulative paint or insulative ink formed by spraying or printing.

18. The process as claimed in claim 9, further comprising a step of pre-treating the substrate before forming the color layer.

19. The process as claimed in claim 18, wherein the pre-treating process comprising ultrasonic cleaning the substrate and plasma cleaning the substrate.

20. The process as claimed in claim 19, wherein plasma cleaning of the substrate uses argon as a working gas, the argon has a flow rate of about 100 sccm-200 sccm; the substrate has a negative bias voltage of about −300 V to about −500 V; plasma cleaning of the substrate takes about 5 min-10 min.
